(19) United States
(12) Patent Application Publication
(10) Pub. No.: US 2024/0143889 A1
(43) Pub. Date: May 2, 2024

(54) METHOD, APPARATUS, AND COMPUTER-READABLE STORAGE MEDIUM FOR GENERATING A LAYOUT OF A JOSEPHSON JUNCTION ARRAY

(71) Applicant: Alibaba Damo (Hangzhou) Technology Co., Ltd., Hangzhou, Zhejiang (CN)

(72) Inventors: Jianjun CHEN, Hangzhou, Zhejiang (CN); Tian XIA, Hangzhou, Zhejiang (CN); Feng WU, Hangzou, Zhejiang (CN); Huihai ZHAO, Beijing (CN); Ran GAO, Hangzhou, Zhejiang (CN); Fei WANG, Hangzhou, Zhejiang (CN); Xiangsheng GU, Hangzhou, Zhejiang (CN); Chunqing DENG, Hangzhou, Zhejiang (CN)

(21) Appl. No.: 18/499,308

(22) Filed: Nov. 1, 2023

(30) Foreign Application Priority Data
Nov. 2, 2022 (CN) 202211362778.8

(51) Int. Cl. G06F 30/392; G06F 30/394

(52) U.S. Cl. CPC G06F 30/392; G06F 30/394

(57) ABSTRACT

A method for generating a layout of a Josephson junction array includes obtaining an original script, in which geometric and action parameters are defined in the original script, the geometric parameters comprise a first structural parameter and a second structural parameter, the action parameters comprise an initial position parameter and a connection parameter; obtaining a first parameter value, a second parameter value, an initial position value, and a connection parameter value; in the original script, respectively assigning the first parameter value, the second parameter value, the initial position value, and the connection parameter value to the first structural parameter, the second structural parameter, the initial position parameter, and the connection parameter, so as to obtain a target script; and performing the target script to obtain a layout of a Josephson junction array having multiple connected Josephson junctions.

### CROSS-REFERENCE TO RELATED APPLICATIONS

The present application claims priority to and the benefits of Chinese Patent Application No. 202211362778.8, filed on Nov. 2, 2022, which is incorporated herein by reference in its entirety.

### TECHNICAL FIELD

The present disclosure relates to the field of layout design, specifically to a layout generation method of a Josephson junction array and a computer-readable storage medium.

### BACKGROUND

In related technologies, in the process of layout design of a quantum chip, a large number of operations need to be completed manually, and the operations are complicated, resulting in very low efficiency in completing the layout design. For example, in the process of layout design of a Josephson junction array, the Josephson junction array is obtained by connecting Josephson junctions in series. The generation of the Josephson junction array as well as the arrangement and error correction of the Josephson junction array need to be completed manually, so that the automation level is low, and the work of a user is extremely complicated.

Therefore, in related technologies, there are technical problems of complicated operations and low efficiency during layout design of a Josephson junction array.

### SUMMARY

Embodiments of the present disclosure provide a method for generating a layout of a Josephson junction array. The method includes: obtaining an original script that defines geometric parameters and action parameters, in which the geometric parameters comprise a first structural parameter used for defining a geometric structure of a Josephson junction and a second structural parameter used for defining a geometric structure of a metal wire configured to connect two adjacent Josephson junctions, the action parameters comprise an initial position parameter used for defining an initial position of an initial Josephson junction and a connection parameter used for defining a connection condition under which the metal wire connects two adjacent Josephson junctions; obtaining a first parameter value of the first structural parameter, a second parameter value of the second structural parameter, an initial position value of the initial position parameter, and a connection parameter value of the connection parameter; obtaining a target script by assigning from the original script: the first parameter value to the first structural parameter, the second parameter value to the second structural parameter, the initial position value to the initial position parameter, and the connection parameter value to the connection parameter; and performing the target script to obtain a layout of a Josephson junction array having a plurality of connected Josephson junctions.

Embodiments of the present disclosure provide a non-transitory computer-readable storage medium. The non-transitory computer-readable storage medium stores a program that is executable by a device to cause the device to perform operations including: obtaining an original script that defines geometric parameters and action parameters, in which the geometric parameters comprise a first structural parameter used for defining a geometric structure of a Josephson junction and a second structural parameter used for defining a geometric structure of a metal wire configured to connect two adjacent Josephson junctions, the action parameters comprise an initial position parameter used for defining an initial position of an initial Josephson junction and a connection parameter used for defining a connection condition under which the metal wire connects two adjacent Josephson junctions; obtaining a first parameter value of the first structural parameter, a second parameter value of the second structural parameter, an initial position value of the initial position parameter, and a connection parameter value of the connection parameter; obtaining a target script by assigning from the original script: the first parameter value to the first structural parameter, the second parameter value to the second structural parameter, the initial position value to the initial position parameter, and the connection parameter value to the connection parameter; and performing the target script to obtain a layout of a Josephson junction array having a plurality of connected Josephson junctions.

Embodiments of the present disclosure provide a computer device. The computer device includes a memory configured to store a computer program and one or more processors configured to run the computer program stored in the memory, to cause the computer device to execute operations including: obtaining an original script that defines geometric parameters and action parameters, in which the geometric parameters comprise a first structural parameter used for defining a geometric structure of a Josephson junction and a second structural parameter used for defining a geometric structure of a metal wire configured to connect two adjacent Josephson junctions, the action parameters comprise an initial position parameter used for defining an initial position of an initial Josephson junction and a connection parameter used for defining a connection condition under which the metal wire connects two adjacent Josephson junctions; obtaining a first parameter value of the first structural parameter, a second parameter value of the second structural parameter, an initial position value of the initial position parameter, and a connection parameter value of the connection parameter; obtaining a target script by assigning from the original script: the first parameter value to the first structural parameter, the second parameter value to the second structural parameter, the initial position value to the initial position parameter, and the connection parameter value to the connection parameter; and performing the target script to obtain a layout of a Josephson junction array having a plurality of connected Josephson junctions.

Embodiments of the present disclosure provide a Fluxonium quantum bit. The Fluxonium quantum bit includes Josephson junctions, a capacitor, and a Josephson junction array. The Josephson junctions, the capacitor, and the Josephson junction array are connected in parallel. The Josephson junction array is fabricated based on a corresponding layout of the Josephson junction array. The layout of the Josephson junction array is obtained based on a method including: obtaining an original script that defines geometric parameters and action parameters, in which the geometric parameters comprise a first structural parameter used for defining a geometric structure of a Josephson junction and a second structural parameter used for defining a geometric structure of a metal wire configured to connect two adjacent Josephson junctions, the action parameters comprise an initial position parameter used for defining an initial position of an initial Josephson junction and a connection parameter used for defining a connection condition under which the metal wire connects two adjacent Josephson junctions; obtaining a first parameter value of the first structural parameter, a second parameter value of the second structural parameter, an initial position value of the initial position parameter, and a connection parameter value of the connection parameter; obtaining a target script by assigning from the original script: the first parameter value to the first structural parameter, the second parameter value to the second structural parameter, the initial position value to the initial position parameter, and the connection parameter value to the connection parameter; and performing the target script to obtain a layout of a Josephson junction array having a plurality of connected Josephson junctions.

### BRIEF DESCRIPTION OF THE DRAWINGS

The accompanying drawings described herein are intended to provide further understanding of the present disclosure and constitute a part of this application. Exemplary embodiments of the present disclosure and the descriptions thereof are used for explaining the present disclosure rather than constituting the improper limitation to the present disclosure.

FIG. 1 is a block diagram of example hardware structures of a computer terminal for implementing a method for generating a layout of a Josephson junction array, according to some embodiments of the present disclosure.

FIG. 2 is a flowchart of an example method for generating a layout of a Josephson junction array, according to some embodiments of the present disclosure.

FIG. 3 is a flowchart of an example method for generating a layout of a Josephson junction array, according to some embodiments of the present disclosure.

FIG. 4 is a schematic diagram illustrating an example Josephson junction, according to some embodiments of the present disclosure.

FIG. 5 is a schematic diagram illustrating an example Josephson junction array, according to some embodiments of the present disclosure.

FIG. 6 is a schematic diagram illustrating example the fabrication of a Josephson junction by a dual-dip projection method, according to some embodiments of the present disclosure.

FIGS. 7(a)-7(d) are diagrams illustrating examples of layouts meeting requirements and incorrect layouts, according to some embodiments of the present disclosure.

FIG. 8 is a schematic diagram of an example connection relationship between Josephson junctions in a Josephson junction array, according to some embodiments of the present disclosure.

FIG. 9 is a structural block diagram of an example apparatus for generating a layout of a Josephson junction array, according to some embodiments of the present disclosure.

FIG. 10 is a structural block diagram of another example apparatus for generating a layout of a Josephson junction array, according to some embodiments of the present disclosure.

FIG. 11 is a structural block diagram of an example computer terminal, according to some embodiments of the present disclosure.

### DETAILED DESCRIPTION

To make persons skilled in the art better understand the technical solutions in the present disclosure, the technical solutions in the embodiments of the present disclosure will be clearly and completely described below with reference to the accompanying drawings in the embodiments of the present disclosure. Apparently, the described embodiments are merely a part but not all of the embodiments of the present disclosure. All other embodiments obtained by a person of ordinary skill in the art based on the embodiments of the present disclosure shall fall within the protection scope of the present disclosure.

It should be noted that the terms such as “first” and “second” in this specification, the claims, and the foregoing accompanying drawings of the present disclosure are intended to distinguish similar objects rather than describe a particular sequence or a chronological order. It is to be understood that data used in this way is exchangeable in a proper case, so that the embodiments of the present disclosure described herein can be implemented in an order different from the order shown or described herein. Moreover, the terms “include”, “contain” and any other variants mean to cover the non-exclusive inclusion, for example, a process, method, system, product, or device that includes a series of steps or units is not necessarily limited to those expressly listed steps or units, but may include other steps or units not expressly listed or inherent to such a process, method, system, product, or device.

Embodiments of the present disclosure provide a layout generation method of a Josephson junction array and a computer-readable storage medium to at least solve technical problems of complicated operations and low efficiency during layout design of a Josephson junction array in related technologies.

A Josephson junction refers to a superconductor-insulator-superconductor (SIS) sandwich structure. A quasi-particle superconducting Cooper pair in the superconductor at one end can tunnel through the sandwich insulator and then arrive at the superconductor at the other end. The tunneling phenomenon of Josephson junctions exhibits lossless and nonlinear inductance and thus is used for core components of superconducting quantum bits.

A single Josephson junction exhibits a nonlinear inductance effect under superconducting conditions. By connecting a plurality of Josephson junctions in series, the nonlinearity can be greatly reduced, and the features of linear inductance can be exhibited. By using the Josephson junction array, the same effect as a classical inductor can be achieved with a very small area, so the Josephson junction array is suitable to be integrated into a quantum bit circuit.

In the embodiments of the present disclosure, by using scripts, parameters for generating a layout of a Josephson junction array and the relationship between the parameters are defined in an original script, values of the parameters are obtained according to actual application needs, and the corresponding values of the parameters are assigned to the parameters in the original script to obtain a target script. The target script is performed to generate a layout of a Josephson junction array that meets the needs. Furthermore, after a layout of a Josephson junction array is generated by using the target script, when it is necessary to generate other types or sizes of Josephson junction arrays, the layout of the Josephson junction array can be modified or adjusted directly by adjusting the adjustable parameters in the script. Moreover, the accuracy obtained by directly adjusting parameters is much higher than the accuracy obtained by manually dragging and adjusting the layout in related technologies (for example, by dragging and adjusting the Josephson junctions in the generated Josephson junction array), thereby achieving the technical effects of avoiding a large number of complicated manual operations in the design process of the layout of the Josephson junction array and improving the layout design efficiency, and further solving the technical problems of complicated operations and low efficiency during layout design of a Josephson junction array in related technologies.

According to some embodiments of the present disclosure, a layout generation method of a Josephson junction array is further provided. It should be noted that the steps shown in the flowchart of the accompanying drawing may be performed in a computer system such as a set of computer executable instructions. Moreover, although a logical order is shown in the flowchart, in some cases, the steps shown or described may be performed in an order different from the order here.

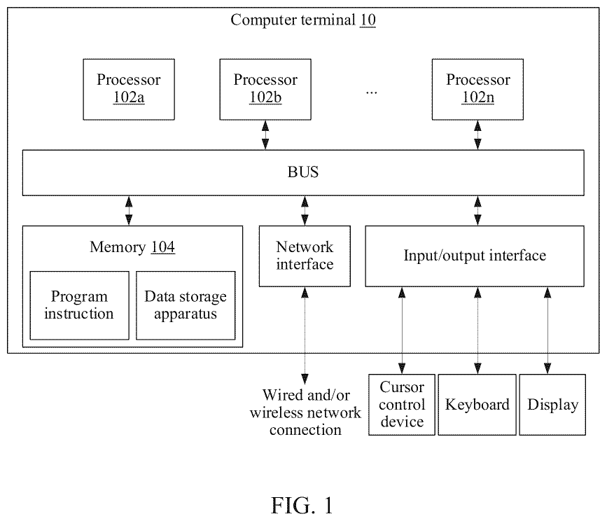

The method provided in some embodiments of the present disclosure may be performed in a mobile terminal, a computer terminal, or a similar arithmetic unit. FIG. 1 shows a block diagram of hardware structures of a computer terminal (or a mobile device) for implementing a method for generating a layout of a Josephson junction array. As shown in FIG. 1, a computer terminal 10 (or a mobile device) may include one or more processors (shown as processors 102a, 102b, . . . , 102n in the figure, and the processor may include, but is not limited to, processing apparatuses such as a microprocessor unit (MCU) or a field programmable gate array (FPGA)), a memory 104 configured to store data, and a transmission apparatus with a communication function. In addition, the computer terminal 10 may further include: a display, an input/output interface (I/O interface), a universal serial bus (USB) port (which may be included as one of the ports of a BUS), a network interface, a power source, and/or a camera. Those of ordinary skill in the art can understand that the structure shown in FIG. 1 is only an example and does not limit the structure of the foregoing electronic apparatus. For example, the computer terminal 10 may further include components more or less than the components shown in FIG. 1, or may have a configuration different from the configuration shown in FIG. 1.

It should be noted that one or more processors and/or other data processing circuits mentioned above may be usually referred to as “data processing circuits” herein. The data processing circuit may be fully or partially embodied as software, hardware, firmware, or any other combination. In addition, the data processing circuit may be an independent processing module, or may be fully or partially integrated into any one of the other components in the computer terminal 10 (or the mobile device). As mentioned in the embodiments of the present disclosure, the data processing circuit serves as a processor control (such as choice of a variable resistor terminal path connected to an interface).

The memory 104 may be configured to store software programs and modules of application software, such as program instructions/data storage apparatuses corresponding to the layout generation method in the embodiments of the present disclosure. The processor executes various functional applications and data processing by running the software programs and modules stored in the memory 104, thereby implementing the method of the foregoing application program. The memory 104 may include a high-speed random access memory, and may further include a non-volatile memory, for example, one or more magnetic storage apparatuses, a flash memory, or another non-volatile solid-state memory. In some embodiments, the memory 104 may further include memories remotely disposed relative to the processor, and the remote memories may be connected to a computer terminal 10 through a network. Examples of the network include, but are not limited to, the Internet, an intranet, a local area network, a mobile communication network, and a combination thereof.

The transmission apparatus is configured to receive or send data through a network. A specific example of the foregoing network may include a wireless network provided by a communication supplier of the computer terminal 10. In some embodiments, the transmission apparatus includes a network interface controller (NIC). The NIC may be connected to another network device through a base station, so as to communicate with the Internet. In some embodiments, the transmission apparatus may be a radio frequency (RF) module, which communicates with the Internet wirelessly.

The display may be a touch screen type liquid crystal display (LCD). The LCD can enable a user to interact with a user interface of the computer terminal 10 (or the mobile device).

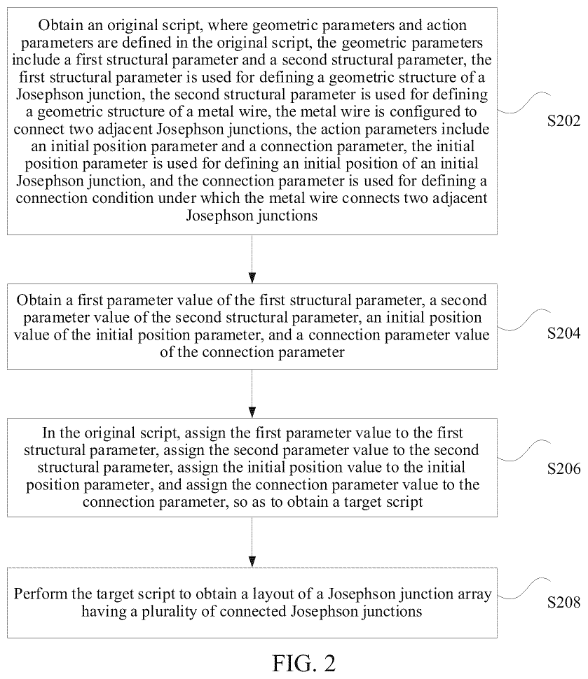

In the foregoing operating environment, the present disclosure provides a method for generating a layout of a Josephson junction array as shown in FIG. 2. FIG. 2 shows a flowchart of an example method for generating a layout of a Josephson junction array according to some embodiments of the present disclosure. As shown in FIG. 2, the method includes following steps S202, S204, S206, and S208.

In step S202, an original script is obtained. Geometric parameters and action parameters are defined in the original script. The geometric parameters include a first structural parameter and a second structural parameter. The first structural parameter is used for defining the geometric structure of a Josephson junction. The second structural parameter is used for defining the geometric structure of a metal wire. The metal wire is configured to connect two adjacent Josephson junctions. The action parameters include an initial position parameter and a connection parameter. The initial position parameter is used for defining an initial position of an initial Josephson junction. The connection parameter is used for defining a condition under which the metal wire connects two adjacent Josephson junctions.

In some embodiments, in the original script, Josephson junctions may be located by coordinates, and relative positions between Josephson junctions may be represented by the relative position relationship between Josephson junctions. For example, for a target Josephson junction in a two-dimensional space, an absolute position of the target Josephson junction may be represented by a horizontal coordinate and a vertical coordinate of the target Josephson junction in the two-dimensional space. The Josephson junction is a structure with a certain size. Therefore, when another Josephson junction is connected to the target Josephson junction, a certain connection relationship exists. When the target Josephson junction is connected to another Josephson junction at different positions of the target Josephson junction, the final obtained Josephson junction arrays are also different. Therefore, the relative position between the target Josephson junction and the connected Josephson junction can be determined by locating the relative position relationship between the target Josephson junction and the connected Josephson junction. It should be noted that since a plurality of Josephson junctions are connected in series in the Josephson junction array, the Josephson junctions that form the entire Josephson junction array are the same. Therefore, as long as one of the Josephson junctions (such as an initial Josephson junction) is determined, the entire Josephson junction array can be obtained by determining the position relationship among the Josephson junction and other Josephson junctions. In addition, another Josephson junction connected to the Josephson junction mentioned above may be the previous Josephson junction before the Josephson junction, or the next Josephson junction following the Josephson junction. Here, there is no limitation on the previous or next Josephson junction as long as the entire Josephson junction array can be determined. For example, in the original script, a vector point can be used for representing a Josephson junction. The vector point includes a coordinate parameter and a direction parameter. The coordinate parameter represents a central coordinate position of the represented Josephson junction. The direction parameter represents a direction position of the next Josephson junction of the represented Josephson junction relative to the represented Josephson junction. The direction position may be a position determined based on a specific structural shape of a Josephson junction. For example, when the Josephson junction is a square, the direction position of the next Josephson junction relative to the current Josephson junction may be a left-turning vertical direction, a right-turning vertical direction, or the like. For another example, when the Josephson junction is a square, due to the fact that the square has four corners, the connection between the Josephson junction and another Josephson junction can be described based on the four corners. For example, the four corners of the Josephson junction can be labeled as A, B, C, and D. In this way, the connection manner between the Josephson junction and another Josephson junction may be a connection between the corner D of the current Josephson junction and the corner A of another Josephson junction, or a connection between the corner C of the current Josephson junction and the corner B of another Josephson junction.

In some embodiment, the foregoing geometric parameters are used for representing components in the Josephson junction array, including Josephson junctions and a metal wire for connecting the Josephson junctions. Therefore, in the original script, the geometric structure for defining the Josephson junction array includes a first structural parameter for defining the geometric structure of the Josephson junction and a second structural parameter for defining the geometric structure of the metal wire. The geometric structure of the Josephson junction includes geometric information such as the shape and size of the Josephson junction. There are multiple types of geometric information, such as a length, a width, a thickness, a plane, or a curved surface. For example, when the Josephson junction is a square, the first structural parameter for defining the geometric structure of the Josephson junction may be the length and width of the Josephson junction, and the second structural parameter for defining the geometric structure of the metal wire may be the length, width, or the like of the metal wire.

In some embodiments, the foregoing action parameters are used for describing a framework of the entire Josephson junction array by defining an initial Josephson junction of the Josephson junction array and then defining a connection manner between Josephson junctions. Since the Josephson junctions in the entire Josephson junction array are the same, as long as a connection condition between two adjacent Josephson junctions is determined, a connection parameter of the connection condition can be represented.

In some embodiments, when geometric parameters and action parameters are defined in the original script and values of the corresponding parameters are obtained, multiple manners may be used. For example, the following manner may be used: geometric parameter types included in the geometric parameters and action parameter types included in the action parameters are determined respectively, and geometric parameter values corresponding to the geometric parameter types and action parameter values corresponding to the action parameter types are obtained respectively, and the geometric parameter values and the action parameter values are used as corresponding parameter values. The geometric parameters can be configured to set geometric information such as the shape and size of components (e.g., Josephson junctions and metal wires). There are multiple geometric parameter types of the geometric parameters, such as the length, the width, the thickness, the plane, and the curved surface. The action parameters can be configured to set editing actions for components. There are also multiple action parameter types of the action parameters, such as movement and rotation. The sizes or editing actions of components are set and adjusted by combining the geometric parameters and the action parameters, so that the components can be more accurately determined, and the accuracy of generation of a layout of a Josephson junction array can be improved.

In some embodiments, based on the design requirements of the entire Josephson junction array, the foregoing connection condition may be set as: one Josephson junction having no more than one adjacent Josephson junction in a horizontal direction and no more than one adjacent Josephson junction in a vertical direction. The foregoing design requirements may be achieved in multiple ways, such as an expression of a value type in mathematics, or by using the foregoing vector point and connecting vector points.

In some embodiments, the connection parameter is represented by a floating point number corresponding to a Josephson junction, the magnitude of the floating point number represents a distance between the corresponding Josephson junction and the previous Josephson junction, and a direction sign of the floating point number represents a direction of the corresponding Josephson junction relative to the previous Josephson junction. It should be noted that when the floating point number is used for representation, the meaning is represented clearly and simply, and scripts can run through programs quickly and efficiently. In addition, the use of the floating point number for representation here as well as the relationship between the Josephson junction and the previous Josephson junction is only an example, and the specific representation manner is not limited herein.

In some embodiments, the direction sign includes: a first direction sign and a second direction sign. The first direction sign represents a left-turning vertical direction of the corresponding Josephson junction relative to the previous Josephson junction. The second direction sign represents a right-turning vertical direction of the corresponding Josephson junction relative to the previous Josephson junction. The foregoing distance and direction representation manner can efficiently and accurately achieve the purpose that one Josephson junction has no more than one adjacent Josephson junction in a horizontal direction and no more than one adjacent Josephson junction in a vertical direction. The foregoing left-turning vertical direction and right-turning vertical direction are described for the Josephson junction as a whole relative to another Josephson junction. For example, when the Josephson junction is a square, the left-turning vertical direction may be described relative to the previous Josephson junction, and the Josephson junction is located at the left-turning 90-degree direction position of the previous Josephson junction; and the right-turning vertical direction may be described relative to the previous Josephson junction, and the Josephson junction is located at the right-turning 90-degree direction position of the previous Josephson junction.

In step S204, a first parameter value of the first structural parameter, a second parameter value of the second structural parameter, an initial position value of the initial position parameter, and a connection parameter value of the connection parameter are obtained.

In some embodiments, when the first parameter value of the first structural parameter, the second parameter value of the second structural parameter, the initial position value of the initial position parameter, and the connection parameter value of the connection parameter are obtained, values corresponding to the parameters can be determined corresponding to the positions of the parameters in codes corresponding to the script interface based on the script interface. Of course, in order to provide a more intuitive parameter input process, a parameter input interface can be provided for parameter settings. Corresponding parameter types are labeled on the parameter input interface. When setting each parameter, the user does not need to read the entire specific codes and can directly set the needed parameter value.

In step S206, in the original script, the first parameter value is assigned to the first structural parameter, the second parameter value is assigned to the second structural parameter, the initial position value is assigned to the initial position parameter, and the connection parameter value is assigned to the connection parameter, so as to obtain a target script.

In some embodiments, when the corresponding parameter value is assigned to the corresponding parameter, the foregoing specific parameter value can be simply verified. For example, whether the set parameter value meets the requirements of the corresponding parameter can be easily determined. For example, for a structural parameter, whether a numerical value corresponding to a size is inputted can be determined. For a position parameter, whether corresponding position coordinates are inputted can be determined. For a connection parameter, whether a judging condition or condition setting is inputted can be determined.

In step S208, the target script is performed to obtain a layout of a Josephson junction array having the plurality of connected Josephson junctions.

In some embodiments, when the target script is performed, computer resources can be used to run program scripts, so that after script programs run, a layout of a Josephson junction array having the plurality of connected Josephson junctions is obtained.

Through the foregoing steps, by using scripts, parameters for generating a layout of a Josephson junction array and the relationship between the parameters are defined in an original script, values of the parameters are obtained according to actual application needs, and the corresponding values of the parameters are assigned to the parameters in the original script to obtain a target script. The target script is performed to generate a layout of a Josephson junction array that meets the needs. Furthermore, after the layout of the Josephson junction array is generated by using the target script, when it is necessary to generate other types or sizes of Josephson junction arrays, the layout of the Josephson junction array can be modified or adjusted directly by adjusting the adjustable parameters in the script. Moreover, the accuracy obtained by directly adjusting parameters is much higher than the accuracy obtained by manually dragging and adjusting the layout in related technologies (for example, by dragging and adjusting the Josephson junctions in the generated Josephson junction array), thereby achieving the technical effects of avoiding a large number of complicated manual operations in the design process of the layout of the Josephson junction array and improving the layout design efficiency, and further solving the technical problems of complicated operations and low efficiency during layout design of a Josephson junction array in related technologies.

In some embodiments, when the layout of a Josephson junction array is generated by using scripts, the user does not need to have professional script knowledge and only needs to set the corresponding parameters accordingly and obtain the values of the corresponding parameters to generate a desired layout of the Josephson junction array, thereby effectively achieving the purpose that professional requirements of scripts are not required for users.

In some embodiments, in a case that the action parameter further includes an adjustment parameter for adjusting the Josephson junction, performing the target script to obtain the layout of the Josephson junction array having the plurality of connected Josephson junctions includes: after the initial position value is assigned to the initial position parameter in the target script, assigning the first parameter value to the first structural parameter in the target script to obtain a Josephson junction; and after the obtained Josephson junction is adjusted according to the adjustment parameter to obtain an adjusted Josephson junction, assigning the second parameter value to the second structural parameter in the target script, and assigning the connection parameter value to the connection parameter, so as to obtain the layout of the Josephson junction array having the plurality of connected Josephson junctions. By using the foregoing processing manner, when the Josephson junction is determined according to the first structural parameter of the Josephson junction, the entire Josephson junction is adjusted according to the corresponding adjustment parameter to obtain an adjusted Josephson junction. Then, the adjusted Josephson junctions are connected. In this way, the Josephson junction is determined first, and then the Josephson junction is adjusted, thereby effectively avoiding the repeated impact on the Josephson junction caused by first connecting the Josephson junctions and then adjusting the Josephson junctions.

After the layout of the Josephson junction array is generated by using the target script, the layout of the Josephson junction array can be modified or adjusted directly by adjusting the parameters in the script. Moreover, the accuracy obtained by directly adjusting parameters is much higher than the accuracy obtained by manually dragging and adjusting the layout in related technologies, thereby achieving the technical effects of avoiding a large number of complicated manual operations in the design process of the layout of the Josephson junction array and improving the layout design efficiency.

In some embodiments, the adjustment parameter includes at least one of: a flipping parameter for a flipping operation of the Josephson junction, or a translation parameter for a translation operation of the Josephson junction. It should be noted that the foregoing flipping and translation operations for the Josephson junction are only an example, and other operations (such as rotation) for the Josephson junction also belong to a portion of the present disclosure.

In some embodiments, when performing the target script to obtain the layout of the Josephson junction array having the plurality of connected Josephson junctions, in the target script, in addition to the parameters listed above, some other parameters which can be accepted by program scripts may also be set. For example, different Josephson junction arrays may include different quantities of Josephson junctions. In order to facilitate efficient generation of the Josephson junction array, a value of a quantity parameter in the target script can be obtained first, where the quantity parameter is used for configuring the quantity of the plurality of Josephson junctions. After the value is assigned to the quantity parameter, the target script is performed to obtain the layout of the Josephson junction array connected with the Josephson junctions, where the quantity of the Josephson junctions is the assigned value. Based on the manner of parameter setting, quantity parameters which can be flexibly adjusted are configured in the target script. Based on the different configured quantity parameters, the layout of the Josephson junction array connected with a needed quantity parameter value of Josephson junctions can be obtained.

In some embodiments, after performing the target script to obtain the layout of the Josephson junction array having the plurality of connected Josephson junctions, the method further includes: creating a target macro based on the target script, where the target macro is used for batch generation of reuse scripts of the Josephson junction array; and generating a replicated layout of the Josephson junction array based on the target macro. If some quantum devices in a quantum chip need to be frequently used in batch, for example, when the Josephson junction array needs to be used in batch or repeatedly, in order to improve the efficiency of generation of the needed layout of the Josephson junction array, a target macro can be created based on the foregoing target script. Then, the target macro can be used for batch generation of reuse scripts of the Josephson junction array, thereby eliminating the trouble of repeatedly determining the Josephson junction array multiple times. In addition, the target macro may be created not only by a single Josephson junction array, but also by a sub-structure formed by a plurality of Josephson junction arrays. As long as it needs to be reused in the layout, the efficiency of generation of the corresponding layout can be improved by creating a target macro.

When the target macro is used for batch generation of scripts of the Josephson junction array, a parameter modification interface of the target macro can be used for adjusting specific parameters in the script to be generated in batch. For example, a set of parameters can be configured in batch in the target macro, and the parameters correspond to a Josephson junction array to be generated. By using this method to determine the script corresponding to the Josephson junction array, on the one hand, scripts corresponding to a plurality of Josephson junction arrays can be obtained very efficiently by using the script, and on the other hand, the flexibility and accuracy in adjusting the parameters in the script are also ensured.

In some embodiments, after performing the target script to obtain the layout of the Josephson junction array having the plurality of connected Josephson junctions, the method further includes: preparing a quantum device including the Josephson junction array based on the layout. There may be multiple types of quantum devices. For example, the quantum device may include at least one of: a Fluxonium quantum bit, a quantum port, a ground plane, a coplanar waveguide, or a quantum component constructed based on the Fluxonium quantum bit.

In some embodiments, after performing the target script to obtain a layout of a Josephson junction array having the plurality of connected Josephson junctions, when the Josephson junction array needs to be outputted and displayed, multiple manners may be used. For example, the following manner may be used: receiving a layout drawing instruction; and in response to the layout drawing instruction, calling a third-party drawing application to draw the layout of the Josephson junction array. It should be noted that there may be multiple types of third-party drawing applications. For example, the third-party drawing application may be commonly used CAD drawing software, Mypaint drawing software, or the like.

It should be noted that in some embodiments, an existing layout can also be directly imported into the current layout. For this portion, various Josephson junction arrays in the imported portion can be determined by manual marking or automatic recognition, and thus, the imported layout can be directly applied.

It should be noted that in some embodiments, the Hamiltonian can also be simulated or calculated according to the generated layout of the Josephson junction array, and the layout of the Josephson junction array can also be efficiently and accurately adjusted according to simulation or calculation results in the form of label box selection and parameter modification.

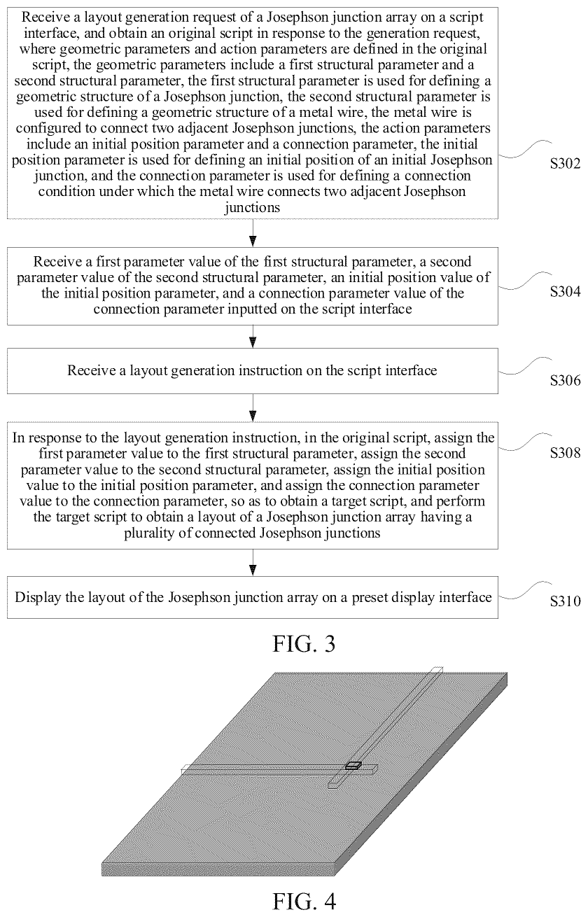

FIG. 3 is a flowchart of an example method for generating a layout of a Josephson junction array, according to some embodiments of the present disclosure. As shown in FIG. 3, the method includes the following steps S302-S310.

In step S302, a layout generation request of a Josephson junction array is received on a script interface. An original script is obtained in response to the generation request. Geometric parameters and action parameters are defined in the original script. The geometric parameters include a first structural parameter and a second structural parameter. The first structural parameter is used for defining a geometric structure of a Josephson junction. The second structural parameter is used for defining a geometric structure of a metal wire. The metal wire is configured to connect two adjacent Josephson junctions. The action parameters include an initial position parameter and a connection parameter. The initial position parameter is used for defining an initial position of an initial Josephson junction. The connection parameter is used for defining a condition under which the metal wire connects two adjacent Josephson junctions.

In step S304, a first parameter value of the first structural parameter, a second parameter value of the second structural parameter, an initial position value of the initial position parameter, and a connection parameter value of the connection parameter inputted on the script interface are received.

In step S306, a layout generation instruction is received on the script interface.

In step S308, in response to the layout generation instruction, in the original script, the first parameter value is assigned to the first structural parameter, the second parameter value is assigned to the second structural parameter, the initial position value is assigned to the initial position parameter, and the connection parameter value is assigned to the connection parameter, so as to obtain a target script, and the target script is performed to obtain a layout of a Josephson junction array having the plurality of connected Josephson junctions.

In step S310, the layout of the Josephson junction array is displayed on a preset display interface.

Through the foregoing steps, by interactions on the script interface, parameters for generating the layout of the Josephson junction array and the relationship between the parameters are defined in an original script. Then, values of the parameters are obtained according to actual application needs, and the corresponding values of the parameters are assigned to the parameters in the original script to obtain a target script. The target script is performed to generate the layout of the Josephson junction array that meets the needs and display the generated layout of the Josephson junction array on the preset display interface. Furthermore, after the layout of the Josephson junction array is generated by using the target script, when it is necessary to generate other types or sizes of Josephson junction arrays, the layout of the Josephson junction array can be modified or adjusted directly by adjusting the adjustable parameters in the script on the script interface. Moreover, the accuracy obtained by directly adjusting parameters is much higher than the accuracy obtained by manually dragging and adjusting the layout in related technologies (for example, by dragging and adjusting the Josephson junctions in the generated Josephson junction array), thereby avoiding a large number of complicated manual operations in the design process of the layout of the Josephson junction array and improving the layout design efficiency. Moreover, the entire process is implemented by interactions on the script interface to achieve the technical effect of effectively improving the intuitiveness of the entire process, thereby solving the technical problems of complicated operations and low efficiency during the layout design of the Josephson junction array in related technologies.

Based on the foregoing embodiments, another implementation is provided in the present disclosure, which is described below.

The Josephson junction array is an important inductance component in a superconducting quantum bit circuit. To achieve the same inductance, the area required by the Josephson junction array is much less than the area required by a geometric inductor, so that the Josephson junction array has higher quality and better integration level. The inductance value provided by a single Josephson junction is limited, so in order to achieve the design objectives, dozens or hundreds of Josephson junctions need to be connected in series. The pattern of the layout of the Manhattan type Josephson junction array provided in some embodiments can be formed by splicing multiple rectangular shapes, which is more suitable for automatic generation by computer programs to reduce the complexity of manual operations and reduce the possibility of errors. Because the requirements for process implementation are converted into program rules, it is possible to generate layout designs meeting the requirements. Manhattan type geometric shapes can be spliced into more abundant geometric shapes based on rectangles, and are characterized in that there are only lines in a horizontal direction and a vertical direction for constituting patterns.

In some embodiments, a design rule for automatic arrangement of superinductors based on the Josephson junction array of a dual-dip process is provided, and a design method and a design tool implementation based on the rule are established. Dual-dip projection method refers to a method for preparing Josephson junctions, which respectively performs metal evaporation from a side (a left side, a right side, an upper side, or a lower side) based on the thickness of a photoresist in a technological process and the limited width of a pattern, and forms an oxide film between two evaporation processes, thereby forming a Josephson junction (SIS) structure. The dual-dip process only requires one mask, which simplifies the technological process, so the dual-dip process is commonly used in the fabrication of Josephson junctions.

Before the Josephson junction array with superinductors formed based on a dual-dip projection method provided in some embodiments is described, the involved Josephson junctions, Josephson junction array and dual-dip projection method are described.

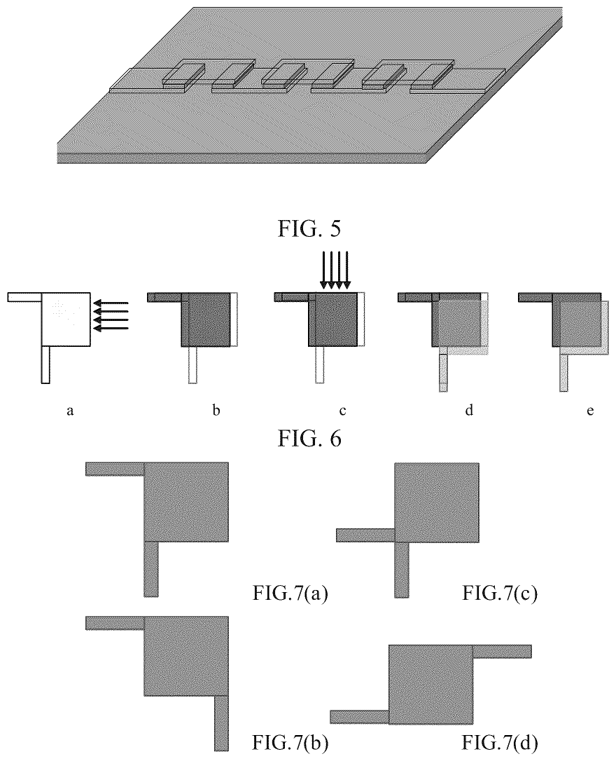

FIG. 4 is a schematic diagram illustrating an example Josephson junction used in some embodiments. As shown in FIG. 4, the Josephson junction includes two cuboid-shaped superconductors and an insulator sandwiched between the superconductors in the figure. FIG. 5 is a schematic diagram illustrating an example Josephson junction array used in some embodiments. As shown in FIG. 5, the Josephson junction array is obtained by connecting a plurality of Josephson junctions in series, which can greatly reduce the nonlinearity of a single Josephson junction and exhibit the characteristics of a linear inductance. By using the Josephson junction array, the same effect as a classical inductor can be achieved in a very small area, so the Josephson junction array is suitable for being integrated into a quantum bit circuit.

FIG. 6 is a schematic diagram illustrating an example fabrication of a Josephson junction by a dual-dip projection method in some embodiments. As shown in FIG. 6, the method includes the following steps: (a) preparing a layout, and performing a first projection; (b) depositing a first layer of metal; (c) performing a second projection; (d) depositing a second layer of metal; and (e) forming the completed Josephson junction with two layers of metal (in which an oxide layer between the metal layers is omitted in the step). By using the foregoing processing manner, metal evaporation processes are performed respectively from the sides (a left side and a right side, or an upper side and a lower side) based on the thickness of a photoresist in the process and the limited width of the pattern, and an oxide film is formed between two evaporation processes, thereby forming a Josephson junction (SIS) structure. The dual-dip process requires one mask, which simplifies the process, so the dual-dip process is commonly used in the fabrication of Josephson junctions.

Based on the foregoing descriptions, for the arrangement of Josephson junctions as the unit forming a superinductor in a dual-dip coating technology for processing superinductors, the following design rule constraints are made in some embodiments.

Firstly, each Josephson junction in the Josephson junction array has a square geometric shape.

Secondly, adjacent Josephson junctions are connected through a thin metal wire.

Thirdly, the Josephson junctions are connected in series to form a superinductor, so except for the Josephson junctions at two ends, they are adjacent to one another.

Fourthly, two thin metal wires in contact with the same Josephson junction are perpendicular to each other, and cannot be located at the same corner of the Josephson junction (to avoid short circuits caused by process defects).

Fifthly, all thin metal wires in a vertical direction are located on the same side of the Josephson junction (default side in the present disclosure).

The first three constraints are design requirements, and the fourth and fifth constraints are derived from process reliability requirements. FIGS. 7(a)-7(d) show examples of layouts meeting requirements and incorrect layouts in some embodiments of the present disclosure. As shown in FIGS. 7(a)-7(d), according to the set rules, FIG. 7(a) and FIG. 7(b) meet the requirements. FIG. 7(c) and FIG. 7(d) do not meet the requirements because two connecting wires in FIG. 7(c) are located at the same corner, and two connecting wires in FIG. 7(d) are parallel.

According to the foregoing rules, a Josephson junction array unit is defined in a script layout design tool in some embodiments of the present disclosure. This unit is defined by a parameter portion and an action portion. The parameter portion defines the size of each Josephson junction square (e.g., a Josephson junction represented by a square) and the width of a metal wire connecting adjacent Josephson junctions. The action portion defines a framework structure of the Josephson junction array, including initial position setting, walking rules, additional rotation and translation operations, or the like.

The Josephson junction array is formed by a series of vector points in a script program. Each vector point contains coordinate information and direction information of the corresponding Josephson junction, and is referred to as a junction in some embodiments. The coordinate information determines the central point position of the Josephson junction square. The direction information determines the position of the next Josephson junction relative to the current Josephson junction (e.g., up, down, left, or right).

The setting of the initial position defines the initial position and direction of the Josephson junction array. The walking rules are formed by a group of floating point number lists. Each floating point number corresponds to a new Josephson junction. The magnitude of the floating point number represents a distance between the current junction and the previous junction. A sign (e.g., positive sign or negative sign) of the floating point number determines the direction of the current junction relative to the previous junction. The positive sign represents the direction of the previous junction turning 90 degrees left. The negative sign represents the direction of the previous junction turning 90 degrees right. The corresponding result is that each junction has no more than one adjacent junction in a horizontal direction and no more than one adjacent junction in a vertical direction.

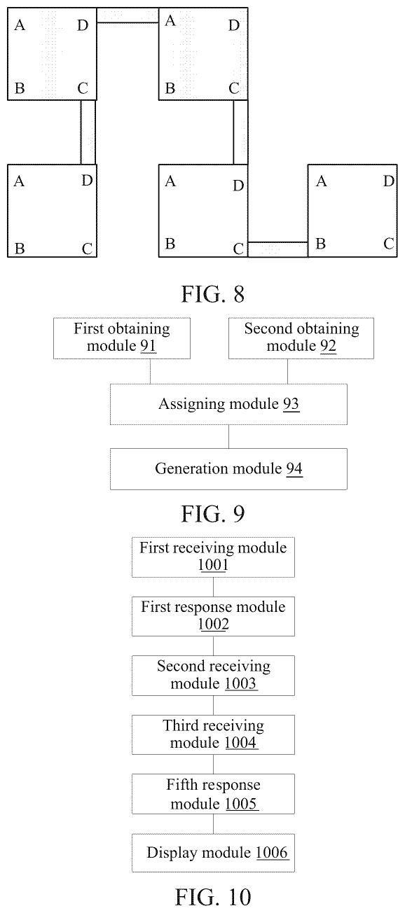

In a program, a layout of a Josephson junction array is generated according to a group of nodes and unit parameters generated by unit actions. FIG. 8 is a schematic diagram of an example connection relationship between Josephson junctions in a Josephson junction array provided in some embodiments. As shown in FIG. 8, taking each junction as a center, a square pattern in a junction area is generated according to the sizes of junctions. Four corners of the square are labeled counterclockwise as A, B, C, and D, and are connected by metal wires between adjacent junctions. In the first step, adjacent junctions in a vertical direction are connected, and then, corresponding junctions are labeled as C or D. Because each junction has no more than one adjacent junction in the vertical direction, C and D cannot be labeled at the same time. In the second step, adjacent junctions in a horizontal direction are connected, and labels of the adjacent junctions are checked. If C or D is labeled, the corner that is not labeled is selected (e.g., if C is occupied, D and A are connected, otherwise, C and B are connected). After two times of connection, all Josephson junctions are connected in series. Then, connecting wires are assigned with lengths, widths and coordinates according to the given parameters to complete the layout. In addition, flipping and translation operations are completed after the junction is determined and before the connecting wire is generated, so there will be no conflict with fourth and fifth rules.

In order to simplify the construction of a unit, the action portions of the unit can be merged according to the repetition of actions. The one-dimensional situation of Manhattan type Josephson junctions can be seen as a periodic arrangement with a forward direction of left, left, right, and right. Therefore, after the user sets an initial junction, the corresponding Josephson junction can be automatically generated by setting the distance between junctions and the quantity of junctions, thereby omitting a large number of repeated steps.

In order to achieve the reuse of the generated Josephson junction array, the macro unit function of the script layout tool can be used for setting a specific Josephson junction array structure as a macro unit. Then, the limited parameters need to be adjusted in the subsequent work to achieve the purpose of reuse, thereby efficiently completing the generation of the layout corresponding to the quantum device.

It should be noted that a script layout tool provided in the foregoing embodiments can also be used for a general layout tool for supporting parameterized units. When the user determines a basic structure of a Josephson junction array and implements a unit, during application, geometric parameters, including the length and the width of a junction and the length and the width of a connecting wire, can be modified according to needs. Thus, the purposes of efficiently and accurately generating needed Josephson junction arrays and quantum device layouts can be achieved.

It should be noted that for each of the foregoing method embodiments, for ease of description, the method is described as a series of action combinations. However, it is appreciated that the present disclosure is not limited to the described order of actions, because according to the present disclosure, some steps may be performed in another order or at the same time. In addition, it is appreciated that the embodiments described in this specification are all exemplary embodiments, and the related actions and modules are not necessarily needed in the present disclosure.

According to the descriptions in the foregoing embodiments, it is appreciated that the method for generating a layout according to the foregoing embodiments may be implemented by relying on software and a necessary universal hardware platform or by using hardware. Based on such understanding, the technical solutions of the present disclosure essentially, or the part contributing to the related technology, may be presented in the form of a software product. The computer software product is stored in a computer-readable storage medium (for example, a ROM/RAM, a magnetic disk, or an optical disc) including several instructions to enable a terminal device (which may be a mobile phone, a computer, a server, a network device, or the like) to perform the methods described in the embodiments of the present disclosure.

According to some embodiments of the present disclosure, an apparatus for implementing the foregoing method for generating a layout of a Josephson junction array in FIG. 2 is further provided. FIG. 9 is a structural block diagram of an example apparatus for generating a layout of a Josephson junction array, according to some embodiments of the present disclosure. As shown in FIG. 9, the apparatus includes a first obtaining module 91, a second obtaining module 92, an assigning module 93, and a generation module 94. The apparatus is described below.

The first obtaining module 91 is configured to obtain an original script. Geometric parameters and action parameters are defined in the original script. The geometric parameters include a first structural parameter and a second structural parameter. The first structural parameter is used for defining a geometric structure of a Josephson junction. The second structural parameter is used for defining a geometric structure of a metal wire. The metal wire is configured to connect two adjacent Josephson junctions. The action parameters include an initial position parameter and a connection parameter. The initial position parameter is used for defining an initial position of an initial Josephson junction. The connection parameter is used for defining a connection condition under which the metal wire connects two adjacent Josephson junctions. The second obtaining module 92 is configured to obtain a first parameter value of the first structural parameter, a second parameter value of the second structural parameter, an initial position value of the initial position parameter, and a connection parameter value of the connection parameter. The assigning module 93 is connected to the first obtaining module 91 and the second obtaining module 92, and is configured to assign the first parameter value to the first structural parameter, assign the second parameter value to the second structural parameter, assign the initial position value to the initial position parameter, and assign the connection parameter value to the connection parameter in the original script, so as to obtain a target script. The generation module 94 is connected to the assigning module 93, and is configured to perform the target script to obtain a layout of a Josephson junction array having the plurality of connected Josephson junctions.

Here, it should be noted that the first obtaining module 91, the second obtaining module 92, the assigning module 93, and the generation module 94 correspond to steps S202 to S210 in the above embodiments. The examples and application scenarios implemented by the foregoing modules and corresponding steps are the same, but are not limited to the content disclosed in the above embodiments. It should be noted that the foregoing module serving as a portion of the apparatus can run in the computer terminal 10 provided in the above embodiments.

According to some embodiments of the present disclosure, another example apparatus for implementing the foregoing method for generating a layout of a Josephson junction array in FIG. 3 is further provided. FIG. 10 is a structural block diagram of an example apparatus for generating a layout of a Josephson junction array, according to some embodiments of the present disclosure.

As shown in FIG. 10, the apparatus includes a first receiving module 1001, a first response module 1002, a second receiving module 1003, a third receiving module 1004, a fifth response module 1005, and a display module 1006. The apparatus is described below.

The first receiving module 1001 is configured to receive a layout generation request of a Josephson junction array on a script interface. The first response module 1002 is configured to obtain an original script in response to the generation request. Geometric parameters and action parameters are defined in the original script. The geometric parameters include a first structural parameter and a second structural parameter. The first structural parameter is used for defining a geometric structure of a Josephson junction. The second structural parameter is used for defining a geometric structure of a metal wire. The metal wire is configured to connect two adjacent Josephson junctions. The action parameters include an initial position parameter and a connection parameter. The initial position parameter is used for defining an initial position of an initial Josephson junction. The connection parameter is used for defining a condition under which the metal wire connects two adjacent Josephson junctions. The second receiving module 1003 is configured to receive a first parameter value of the first structural parameter, a second parameter value of the second structural parameter, an initial position value of the initial position parameter, and a connection parameter value of the connection parameter inputted on the script interface. The third receiving module 1004 is configured to receive a layout generation instruction on the script interface. The fifth response module 1005 is configured to assign the first parameter value to the first structural parameter, assign the second parameter value to the second structural parameter, assign the initial position value to the initial position parameter, and assign the connection parameter value to the connection parameter in the original script in response to the layout generation instruction, so as to obtain a target script, and perform the target script to obtain a layout of a Josephson junction array having the plurality of connected Josephson junctions. The display module 1006 is configured to display the layout of the Josephson junction array on a preset display interface.

Here, it should be noted that the first receiving module 1001, the first response module 1002, the second receiving module 1003, the third receiving module 1004, the fifth response module 1005, and the display module 1006 correspond to steps S302 to S312 in the above embodiments. The examples and application scenarios implemented by the six modules and corresponding steps are the same, but are not limited to the content disclosed in the above embodiments. It should be noted that the foregoing module serving as a portion of the apparatus can run in the computer terminal 10 provided in the above embodiments.

According to some embodiments of the present disclosure, a Fluxonium quantum bit is further provided, including: Josephson junctions, a capacitor, and a Josephson junction array. The Josephson junctions, the capacitor, and the Josephson junction array are connected in parallel. The Josephson junction array is fabricated based on a corresponding layout of the Josephson junction array. The layout of the Josephson junction array is obtained based on any one of the foregoing methods.

In some embodiments of the present disclosure, a computer terminal may be provided. The computer terminal may be any computer terminal device in a computer terminal group. In some embodiments, the foregoing computer terminal may also be replaced with a terminal device such as a mobile terminal.

In some embodiments, the foregoing computer terminal may be located in at least one of a plurality of network devices in a computer network.

In some embodiments, the foregoing computer terminal can execute program codes of the following steps in the method for generating the layout of the Josephson junction array in an application program: obtaining an original script, where geometric parameters and action parameters are defined in the original script, the geometric parameters include a first structural parameter and a second structural parameter, the first structural parameter is used for defining a geometric structure of a Josephson junction, the second structural parameter is used for defining a geometric structure of a metal wire, the metal wire is configured to connect two adjacent Josephson junctions, the action parameters include an initial position parameter and a connection parameter, the initial position parameter is used for defining an initial position of an initial Josephson junction, and the connection parameter is used for defining a condition under which the metal wire connects two adjacent Josephson junctions; obtaining a first parameter value of the first structural parameter, a second parameter value of the second structural parameter, an initial position value of the initial position parameter, and a connection parameter value of the connection parameter; in the original script, assigning the first parameter value to the first structural parameter, assigning the second parameter value to the second structural parameter, assigning the initial position value to the initial position parameter, and assigning the connection parameter value to the connection parameter, so as to obtain a target script; and performing the target script to obtain a layout of a Josephson junction array having the plurality of connected Josephson junctions.

In some embodiments, the foregoing computer terminal can execute program codes of the following steps in the method for generating the layout of the Josephson junction array in the application program: receiving a layout generation request of a Josephson junction array on a script interface; obtaining an original script in response to the generation request, where geometric parameters and action parameters are defined in the original script, the geometric parameters include a first structural parameter and a second structural parameter, the first structural parameter is used for defining a geometric structure of a Josephson junction, the second structural parameter is used for defining a geometric structure of a metal wire, the metal wire is configured to connect two adjacent Josephson junctions, the action parameters include an initial position parameter and a connection parameter, the initial position parameter is used for defining an initial position of an initial Josephson junction, and the connection parameter is used for defining a condition under which the metal wire connects two adjacent Josephson junctions; receiving a first parameter value of the first structural parameter, a second parameter value of the second structural parameter, an initial position value of the initial position parameter, and a connection parameter value of the connection parameter inputted on the script interface; receiving a layout generation instruction on the script interface; in response to the layout generation instruction, in the original script, assigning the first parameter value to the first structural parameter, assigning the second parameter value to the second structural parameter, assigning the initial position value to the initial position parameter, and assigning the connection parameter value to the connection parameter, so as to obtain a target script, and performing the target script to obtain a layout of a Josephson junction array having the plurality of connected Josephson junctions; and displaying the layout of the Josephson junction array on a preset display interface.

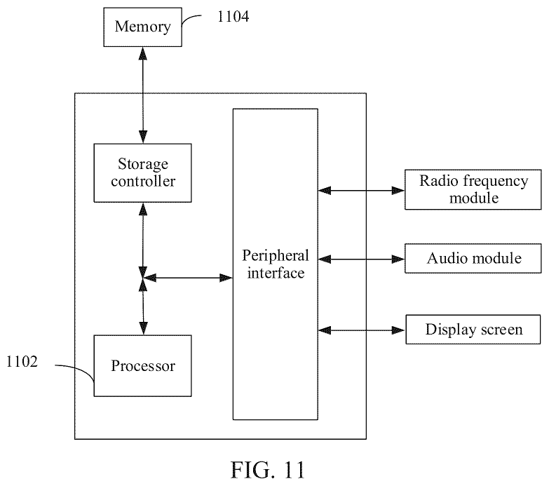

FIG. 11 is a structural block diagram of an example computer terminal, according to some embodiments of the present disclosure. As shown in FIG. 11, the computer terminal may include one or more processors 1102 (only one processor is shown in the figure), a memory 1104, and the like.

The memory may be configured to store software programs and modules, such as program instructions/modules corresponding to the method and apparatus for generating the layout of the Josephson junction array in the embodiments of the present disclosure. The processor executes various functional applications and data processing by running the software programs and modules stored in the memory, thereby implementing the foregoing method for generating the layout of the Josephson junction array. The memory may include a high-speed random access memory, and may further include a non-volatile memory, for example, one or more magnetic storage apparatuses, a flash memory, or another non-volatile solid-state memory. In some embodiments, the memory may further include memories remotely disposed relative to the processor, and the remote memories may be connected to a computer terminal through a network. Examples of the network include, but are not limited to, the Internet, an intranet, a local area network, a mobile communication network, and a combination thereof.

The processor may call the information and application programs stored in the memory through the transmission apparatus to perform the following steps: obtaining an original script, where geometric parameters and action parameters are defined in the original script, the geometric parameters include a first structural parameter and a second structural parameter, the first structural parameter is used for defining a geometric structure of a Josephson junction, the second structural parameter is used for defining a geometric structure of a metal wire, the metal wire is configured to connect two adjacent Josephson junctions, the action parameters include an initial position parameter and a connection parameter, the initial position parameter is used for defining an initial position of an initial Josephson junction, and the connection parameter is used for defining a condition under which the metal wire connects two adjacent Josephson junctions; obtaining a first parameter value of the first structural parameter, a second parameter value of the second structural parameter, an initial position value of the initial position parameter, and a connection parameter value of the connection parameter; in the original script, assigning the first parameter value to the first structural parameter, assigning the second parameter value to the second structural parameter, assigning the initial position value to the initial position parameter, and assigning the connection parameter value to the connection parameter, so as to obtain a target script; and performing the target script to obtain a layout of a Josephson junction array having the plurality of connected Josephson junctions.

In some embodiments, the foregoing processor may further execute program codes of the following steps: in the original script, using a vector point for representing a Josephson junction, in which the vector point includes a coordinate parameter and a direction parameter, the coordinate parameter represents a central coordinate position of the represented Josephson junction, and the direction parameter represents a direction position of the next Josephson junction of the represented Josephson junction relative to the represented Josephson junction.

In some embodiments, the foregoing processor may further execute program codes of the following steps: the connection condition is: one Josephson junction having no more than one adjacent Josephson junction in a horizontal direction and no more than one adjacent Josephson junction in a vertical direction.

In some embodiments, the foregoing processor may further execute program codes of the following steps: the connection parameter is represented by a floating point number corresponding to a Josephson junction, the magnitude of the floating point number represents a distance between the corresponding Josephson junction and the previous Josephson junction, and a direction sign of the floating point number represents a direction of the corresponding Josephson junction relative to the previous Josephson junction.

In some embodiments, the foregoing processor may further execute program codes of the following steps: the direction sign being a first direction sign represents a left-turning vertical direction of the corresponding Josephson junction relative to the previous Josephson junction, and the direction sign being a second direction sign represents a right-turning vertical direction of the corresponding Josephson junction relative to the previous Josephson junction.

In some embodiments, the foregoing processor may further execute program codes of the following steps: in a case that the action parameter further includes an adjustment parameter for adjusting the Josephson junction, performing the target script to obtain the layout of the Josephson junction array having the plurality of connected Josephson junctions includes: after the initial position value is assigned to the initial position parameter in the target script, assigning the first parameter value to the first structural parameter in the target script to obtain the Josephson junction; and after the obtained Josephson junction is adjusted according to the adjustment parameter to obtain an adjusted Josephson junction, assigning the second parameter value to the second structural parameter in the target script, and assigning the connection parameter value to the connection parameter, so as to obtain the layout of the Josephson junction array having the plurality of connected Josephson junctions.

In some embodiments, the foregoing processor may further execute program codes of the following steps: the adjustment parameter includes at least one of: a flipping parameter for a flipping operation of the Josephson junction, or a translation parameter for a translation operation of the Josephson junction.

In some embodiments, the foregoing processor may further execute program codes of the following steps: performing the target script to obtain the layout of the Josephson junction array having the plurality of connected Josephson junctions includes: obtaining a value of a quantity parameter in the target script, where the quantity parameter is used for configuring the quantity of the plurality of Josephson junctions; and after assigning the value to the quantity parameter, performing the target script to obtain the layout of the Josephson junction array having connected Josephson junctions, wherein the quantity of the connected Josephson junctions is the assigned value.

In some embodiments, the foregoing processor may further execute program codes of the following steps: after performing the target script to obtain the layout of the Josephson junction array having the plurality of connected Josephson junctions, creating a target macro based on the target script, where the target macro is used for batch generation of reuse scripts of the Josephson junction array; and generating a replicated layout of the Josephson junction array based on the target macro.

In some embodiments, the foregoing processor may further execute program codes of the following steps: after performing the target script to obtain the layout of the Josephson junction array having the plurality of connected Josephson junctions, preparing a quantum device including the Josephson junction array is prepared based on the layout, where the quantum device includes at least one of: a Fluxonium quantum bit, a quantum port, a ground plane, a coplanar waveguide, or a quantum component constructed based on the Fluxonium quantum bit.

The processor may call the information and application programs stored in the memory through the transmission apparatus to perform the following steps: receiving a layout generation request of a Josephson junction array on a script interface; obtaining an original script in response to the generation request, where geometric parameters and action parameters are defined in the original script, the geometric parameters include a first structural parameter and a second structural parameter, the first structural parameter is used for defining a geometric structure of a Josephson junction, the second structural parameter is used for defining a geometric structure of a metal wire, the metal wire is configured to connect two adjacent Josephson junctions, the action parameters include an initial position parameter and a connection parameter, the initial position parameter is used for defining an initial position of an initial Josephson junction, and the connection parameter is used for defining a connection condition under which the metal wire connects two adjacent Josephson junctions; receiving a first parameter value of the first structural parameter, a second parameter value of the second structural parameter, an initial position value of the initial position parameter, and a connection parameter value of the connection parameter inputted on the script interface; receiving a layout generation instruction on the script interface; in response to the layout generation instruction, in the original script, assigning the first parameter value to the first structural parameter, assigning the second parameter value to the second structural parameter, assigning the initial position value to the initial position parameter, and assigning the connection parameter value to the connection parameter, so as to obtain a target script, and performing the target script to obtain a layout of a Josephson junction array having the plurality of connected Josephson junctions; and displaying the layout of the Josephson junction array on a preset display interface.

By applying the embodiments of the present disclosure, a solution of a method for generating a layout of a Josephson junction array is provided. By using scripts, parameters for generating the layout of the Josephson junction array and the relationship between the parameters are defined in an original script, values of the parameters are obtained according to actual application needs, and the corresponding values of the parameters are assigned to the parameters in the original script to obtain a target script. The target script is performed to generate the layout of the Josephson junction array that meets the needs. Furthermore, after the layout of the Josephson junction array is generated by using the target script, when it is required to generate other types or sizes of Josephson junction arrays, the layout of the Josephson junction array can be modified or adjusted directly by adjusting the adjustable parameters in the script. Moreover, the accuracy obtained by directly adjusting parameters is much higher than the accuracy obtained by manually dragging and adjusting the layout in related technologies (for example, by dragging and adjusting the Josephson junctions in the generated Josephson junction array), thereby achieving the technical effects of avoiding a large number of complicated manual operations in the design process of the layout of the Josephson junction array and improving the layout design efficiency, and further solving the technical problems of complicated operations and low efficiency during layout design of the Josephson junction array in related technologies.

It is appreciated that the structure shown in FIG. 11 is only an example. The computer terminal may also be a terminal device such as a smartphone (such as an Android phone or an iOS phone), a tablet computer, a palmtop computer, a mobile Internet device (MID), or a PAD. FIG. 11 does not limit the structure of the foregoing electronic apparatus. For example, the computer terminal may further include more or fewer components (such as a network interface and a display apparatus) than those shown in FIG. 11, or has a configuration different from that shown in FIG. 11.

It is appreciated that all or some of the steps of the methods in the foregoing embodiments may be completed by a program instructing relevant hardware of a terminal device. The program may be stored in a computer-readable storage medium. The computer-readable storage medium may include: a flash drive, a read-only memory (ROM), a random access memory (RAM), a magnetic disk, an optical disc, or the like.

In some embodiments of the present disclosure, a computer-readable storage medium is further provided. In some embodiments, the foregoing computer-readable storage medium may be configured to store the program codes executed by the method for generating the layout of the Josephson junction array provided in the above embodiments.

In some embodiments, the foregoing computer-readable storage medium may be located in any computer terminal in a computer terminal group in a computer network, or located in any mobile terminal in a mobile terminal group.

In some embodiments, the computer-readable storage medium is configured to store program codes for performing the following steps: obtaining an original script, where geometric parameters and action parameters are defined in the original script, the geometric parameters include a first structural parameter and a second structural parameter, the first structural parameter is used for defining a geometric structure of a Josephson junction, the second structural parameter is used for defining a geometric structure of a metal wire, the metal wire is configured to connect two adjacent Josephson junctions, the action parameters include an initial position parameter and a connection parameter, the initial position parameter is used for defining an initial position of an initial Josephson junction, and the connection parameter is used for defining a connection condition under which the metal wire connects two adjacent Josephson junctions; obtaining a first parameter value of the first structural parameter, a second parameter value of the second structural parameter, an initial position value of the initial position parameter, and a connection parameter value of the connection parameter; in the original script, assigning the first parameter value to the first structural parameter, assigning the second parameter value to the second structural parameter, assigning the initial position value to the initial position parameter, and assigning the connection parameter value to the connection parameter, so as to obtain a target script; and performing the target script to obtain a layout of a Josephson junction array having the plurality of connected Josephson junctions.

In some embodiments, the computer-readable storage medium is configured to store program codes for performing the following steps: in the original script, using a vector point for representing a Josephson junction, the vector point includes a coordinate parameter and a direction parameter, the coordinate parameter represents a central coordinate position of the represented Josephson junction, and the direction parameter represents a direction position of the next Josephson junction of the represented Josephson junction relative to the represented Josephson junction.

In some embodiments, the computer-readable storage medium is configured to store program codes for performing the following steps: the connection condition is: one Josephson junction having no more than one adjacent Josephson junction in a horizontal direction and no more than one adjacent Josephson junction in a vertical direction.

In some embodiments, the computer-readable storage medium is configured to store program codes for performing the following steps: the connection parameter is represented by a floating point number corresponding to the Josephson junction, the magnitude of the floating point number represents a distance between the corresponding Josephson junction and the previous Josephson junction, and a direction sign of the floating point number represents a direction of the corresponding Josephson junction relative to the previous Josephson junction.

In some embodiments, the computer-readable storage medium is configured to store program codes for performing the following steps: the direction sign being a first direction sign represents a left-turning vertical direction of the corresponding Josephson junction relative to the previous Josephson junction, and the direction sign being a second direction sign represents a right-turning vertical direction of the corresponding Josephson junction relative to the previous Josephson junction.

In some embodiments, the computer-readable storage medium is configured to store program codes for performing the following steps: in a case that the action parameter further includes an adjustment parameter for adjusting the Josephson junction, performing the target script to obtain the layout of the Josephson junction array having the plurality of connected Josephson junctions includes: after assigning the initial position value to the initial position parameter in the target script, assigning the first parameter value to the first structural parameter in the target script to obtain a Josephson junction; and after adjusting the obtained Josephson junction according to the adjustment parameter to obtain an adjusted Josephson junction, assigning the second parameter value to the second structural parameter in the target script, and assigning the connection parameter value to the connection parameter, so as to obtain the layout of the Josephson junction array having the plurality of connected Josephson junctions.

In some embodiments, the computer-readable storage medium is configured to store program codes for performing the following steps: the adjustment parameter includes at least one of: a flipping parameter for a flipping operation of the Josephson junction, or a translation parameter for a translation operation of the Josephson junction.

In some embodiments, the computer-readable storage medium is configured to store program codes for performing the following steps: performing the target script to obtain a layout of a Josephson junction array having the plurality of connected Josephson junctions includes: obtaining a value of a quantity parameter in the target script, where the quantity parameter is used for configuring the quantity of the plurality of Josephson junctions; and after assigning the value to the quantity parameter, the target script is performed to obtain the layout of the Josephson junction array having connected Josephson junctions, in which the quantity of the connected Josephson junctions is the assigned value.

In some embodiments, the computer-readable storage medium is configured to store program codes for performing the following steps: after performing the target script to obtain a layout of a Josephson junction array having the plurality of connected Josephson junctions, creating a target macro based on the target script, where the target macro is used for batch generation of reuse scripts of the Josephson junction array; and generating a replicated layout of the Josephson junction array based on the target macro.

In some embodiments, the computer-readable storage medium is configured to store program codes for performing the following steps: after performing the target script to obtain the layout of the Josephson junction array having the plurality of connected Josephson junctions, the method further includes: preparing a quantum device including the Josephson junction array based on the layout, where the quantum device includes at least one of: a Fluxonium quantum bit, a quantum port, a ground plane, a coplanar waveguide, or a quantum component constructed based on the Fluxonium quantum bit.

In some embodiments, the computer-readable storage medium is configured to store program codes for performing the following steps: receiving a layout generation request of a Josephson junction array on a script interface; obtaining an original script in response to the generation request, where geometric parameters and action parameters are defined in the original script, the geometric parameters include a first structural parameter and a second structural parameter, the first structural parameter is used for defining a geometric structure of a Josephson junction, the second structural parameter is used for defining a geometric structure of a metal wire, the metal wire is configured to connect two adjacent Josephson junctions, the action parameters include an initial position parameter and a connection parameter, the initial position parameter is used for defining an initial position of an initial Josephson junction, and the connection parameter is used for defining a condition under which the metal wire connects two adjacent Josephson junctions; receiving a first parameter value of the first structural parameter, a second parameter value of the second structural parameter, an initial position value of the initial position parameter, and a connection parameter value of the connection parameter inputted on the script interface; receiving a layout generation instruction on the script interface; in response to the layout generation instruction, in the original script, assigning the first parameter value to the first structural parameter, assigning the second parameter value to the second structural parameter, assigning the initial position value to the initial position parameter, and assigning the connection parameter value to the connection parameter, so as to obtain a target script, and performing the target script to obtain a layout of a Josephson junction array having the plurality of connected Josephson junctions; and displaying the layout of the Josephson junction array on a preset display interface.

The sequence numbers of the embodiments of the present disclosure are merely for the description purpose but do not imply the preference among the embodiments.

In the foregoing embodiments of the present disclosure, the descriptions of the embodiments have different focuses. For a part that is not detailed in some embodiments, reference may be made to the relevant descriptions of other embodiments.

In several embodiments provided in the present disclosure, it should be understood that the disclosed technical content may be implemented in other manners. The foregoing described apparatus embodiments are merely examples. For example, the unit division is merely logical function division, and there may be other division manners in actual implementations. For example, multiple units or components may be combined or integrated into another system, or some features may be omitted or not performed. In addition, the coupling, or direct coupling, or communication connection between the shown or discussed components may be the indirect coupling or communication connection by some interfaces, units, or modules, and may be electrical or of other forms.

The units described as separate components may or may not be physically separated, and components displayed as units may or may not be physical units, that is, may be located in one position, or may be distributed on a plurality of network units. Some or all of the units may be selected according to actual needs to achieve the objectives of the solutions of the embodiments.

In addition, functional units in the embodiments of the present disclosure may be integrated into one processing unit, or each of the units may be physically separated, or two or more units may be integrated into one unit. The integrated unit may be implemented in the form of hardware, or may be implemented in the form of a software functional unit.

When the integrated unit is implemented in the form of a software functional unit and sold or used as an independent product, the integrated unit may be stored in a computer-readable storage medium. Based on such understanding, the technical solutions of the present disclosure essentially, or the part contributing to the related technology, or all or some of the technical solutions may be presented in the form of a software product. The computer software product is stored in a computer-readable storage medium, and includes several instructions for instructing a computer device (which may be a personal computer, a server, a network device, or the like) to perform all or some of the steps of the methods described in the embodiments of the present disclosure. The foregoing computer-readable storage medium includes: various media capable of storing program codes, such as a USB flash drive, a ROM, a RAM, a mobile hard disk, a magnetic disk, or an optical disc.

The embodiments may further be described using the following clauses:
1: A method for generating a layout of a Josephson junction array, comprising: obtaining an original script that defines geometric parameters and action parameters, wherein the geometric parameters comprise a first structural parameter used for defining a geometric structure of a Josephson junction and a second structural parameter used for defining a geometric structure of a metal wire configured to connect two adjacent Josephson junctions, wherein the action parameters comprise an initial position parameter used for defining an initial position of an initial Josephson junction and a connection parameter used for defining a connection condition under which the metal wire connects two adjacent Josephson junctions; obtaining a first parameter value of the first structural parameter, a second parameter value of the second structural parameter, an initial position value of the initial position parameter, and a connection parameter value of the connection parameter; obtaining a target script by assigning from the original script: the first parameter value to the first structural parameter, the second parameter value to the second structural parameter, the initial position value to the initial position parameter, and the connection parameter value to the connection parameter; and performing the target script to obtain a layout of a Josephson junction array having a plurality of connected Josephson junctions.
2: The method of clause 1, wherein in the original script, the Josephson junction is represented by a vector point, the vector point comprises a coordinate parameter and a direction parameter, the coordinate parameter represents a central coordinate position of the represented Josephson junction, and the direction parameter represents a direction position of the next Josephson junction of the represented Josephson junction relative to the represented Josephson junction.
3: The method of clause 1 or 2, wherein the connection condition is: one Josephson junction having no more than one adjacent Josephson junction in a horizontal direction and no more than one adjacent Josephson junction in a vertical direction.
4: The method of any of clauses 1-3, wherein the connection parameter is represented by a floating point number corresponding to the Josephson junction, the magnitude of the floating point number represents a distance between the corresponding Josephson junction and the previous Josephson junction, and a direction sign of the floating point number represents a direction of the corresponding Josephson junction relative to the previous Josephson junction.
5: The method of any of clauses 1-4, wherein the direction sign being a first direction sign represents a left-turning vertical direction of the corresponding Josephson junction relative to the previous Josephson junction, and the direction sign being a second direction sign represents a right-turning vertical direction of the corresponding Josephson junction relative to the previous Josephson junction.
6: The method of any of clauses 1-5, wherein when the action parameter further comprises an adjustment parameter for adjusting the Josephson junction, performing the target script to obtain the layout of the Josephson junction array having a plurality of connected Josephson junctions comprises: after assigning the initial position value to the initial position parameter in the target script, assigning the first parameter value to the first structural parameter in the target script to obtain the Josephson junction; and after adjusting the obtained Josephson junction according to the adjustment parameter to obtain an adjusted Josephson junction, assigning the second parameter value to the second structural parameter in the target script, and assigning the connection parameter value to the connection parameter, so as to obtain the layout of the Josephson junction array having the plurality of connected Josephson junctions.
7: The method of any of clauses 1-6, wherein the adjustment parameter comprises at least one of: a flipping parameter for a flipping operation of the Josephson junction, or a translation parameter for a translation operation of the Josephson junction.
8: The method of any of clauses 1-7, wherein performing the target script to obtain the layout of the Josephson junction array having the plurality of connected Josephson junctions comprises: obtaining a value of a quantity parameter in the target script, wherein the quantity parameter is used for configuring the quantity of the plurality of Josephson junctions; and after assigning the value to the quantity parameter, performing the target script to obtain the layout of the Josephson junction array having connected Josephson junctions, wherein the quantity of the connected Josephson junctions is the assigned value.
9: The method of any of clauses 1-8, wherein after performing the target script to obtain the layout of the Josephson junction array having the plurality of connected Josephson junctions, the method further comprises: creating a target macro based on the target script, wherein the target macro is used for batch generation of reuse scripts of the Josephson junction array; and generating a replicated layout of the Josephson junction array based on the target macro.
10: The method of any of clauses 1-9, wherein after performing the target script to obtain the layout of the Josephson junction array having the plurality of connected Josephson junctions, the method further comprises: preparing a quantum device comprising the Josephson junction array based on the layout, wherein the quantum device comprises at least one of: a Fluxonium quantum bit, a quantum port, a ground plane, a coplanar waveguide, or a quantum component constructed based on the Fluxonium quantum bit.
11: The method of any of clauses 1-10, further comprising: receiving a layout generation request of the Josephson junction array on a script interface; obtaining the original script in response to the generation request; receiving a layout generation instruction on the script interface; in response to the layout generation instruction, obtaining the target script and performing the target script; and displaying the layout of the Josephson junction array on a preset display interface.
12: A method for generating a layout of a Josephson junction array, comprising: receiving a layout generation request of a Josephson junction array on a script interface; obtaining an original script that defines geometric parameters and action parameters in response to the generation request, wherein the geometric parameters comprise a first structural parameter used for defining a geometric structure of a Josephson junction, and a second structural parameter used for defining a geometric structure of a metal wire configured to connect two adjacent Josephson junctions, wherein the action parameters comprise an initial position parameter used for defining an initial position of an initial Josephson junction and a connection parameter used for defining a connection condition under which the metal wire connects two adjacent Josephson junctions; receiving a first parameter value of the first structural parameter, a second parameter value of the second structural parameter, an initial position value of the initial position parameter, and a connection parameter value of the connection parameter inputted on the script interface; receiving a layout generation instruction on the script interface; in response to the layout generation instruction, obtaining a target script by assigning from the original script: the first parameter value to the first structural parameter, the second parameter value to the second structural parameter, the initial position value to the initial position parameter, and the connection parameter value to the connection parameter; performing the target script to obtain a layout of a Josephson junction array having the plurality of connected Josephson junctions; and displaying the layout of the Josephson junction array on a preset display interface.
13: A Fluxonium quantum bit, comprising: Josephson junctions, a capacitor, and a Josephson junction array, wherein the Josephson junctions, the capacitor, and the Josephson junction array are connected in parallel, the Josephson junction array is fabricated based on a corresponding layout of the Josephson junction array, and the layout of the Josephson junction array is obtained based on a method comprising: obtaining an original script that defines geometric parameters and action parameters, wherein the geometric parameters comprise a first structural parameter used for defining a geometric structure of a Josephson junction and a second structural parameter used for defining a geometric structure of a metal wire configured to connect two adjacent Josephson junctions, wherein the action parameters comprise an initial position parameter used for defining an initial position of an initial Josephson junction and a connection parameter used for defining a connection condition under which the metal wire connects two adjacent Josephson junctions; obtaining a first parameter value of the first structural parameter, a second parameter value of the second structural parameter, an initial position value of the initial position parameter, and a connection parameter value of the connection parameter; obtaining a target script by assigning from the original script: the first parameter value to the first structural parameter, the second parameter value to the second structural parameter, the initial position value to the initial position parameter, and the connection parameter value to the connection parameter; and performing the target script to obtain a layout of a Josephson junction array having a plurality of connected Josephson junctions.
14: A computer-readable storage medium, comprising a stored program, wherein when the program runs, a device on which the computer-readable storage medium is located is controlled to perform a method for generating a layout of a Josephson junction array according to any one of clauses 1-11.
15: A computer device comprising a memory storing a set of instructions; and one or more processors configured to execute the instructions to cause the computer device to perform operations for generating a layout of a Josephson junction array, the operations comprising according to any one of clauses 1-11.
16: A non-transitory computer-readable storage medium storing a program that is executable by a device to cause the device to perform operations comprising: obtaining an original script that defines geometric parameters and action parameters, wherein the geometric parameters comprise a first structural parameter used for defining a geometric structure of a Josephson junction, and a second structural parameter used for defining a geometric structure of a metal wire configured to connect two adjacent Josephson junctions, wherein the action parameters comprise an initial position parameter used for defining an initial position of an initial Josephson junction, and a connection parameter used for defining a connection condition under which the metal wire connects two adjacent Josephson junctions; obtaining a first parameter value of the first structural parameter, a second parameter value of the second structural parameter, an initial position value of the initial position parameter, and a connection parameter value of the connection parameter; obtaining a target script by assigning from the original script: the first parameter value to the first structural parameter, the second parameter value to the second structural parameter, the initial position value to the initial position parameter, and the connection parameter value to the connection parameter; and performing the target script to obtain a layout of a Josephson junction array having a plurality of connected Josephson junctions.
17: The non-transitory computer-readable storage medium of clause 16, wherein in the original script, the Josephson junction is represented by a vector point, the vector point comprises a coordinate parameter and a direction parameter, the coordinate parameter represents a central coordinate position of the represented Josephson junction, and the direction parameter represents a direction position of the next Josephson junction of the represented Josephson junction relative to the represented Josephson junction.
18: The non-transitory computer-readable storage medium as either of clauses 16 or 17, wherein the connection condition is: one Josephson junction having no more than one adjacent Josephson junction in a horizontal direction and no more than one adjacent Josephson junction in a vertical direction.
19: The non-transitory computer-readable storage medium of any of clauses 16-18, wherein the connection parameter is represented by a floating point number corresponding to the Josephson junction, the magnitude of the floating point number represents a distance between the corresponding Josephson junction and the previous Josephson junction, and a direction sign of the floating point number represents a direction of the corresponding Josephson junction relative to the previous Josephson junction.
20: The non-transitory computer-readable storage medium of any of clauses 16-19, wherein the direction sign being a first direction sign represents a left-turning vertical direction of the corresponding Josephson junction relative to the previous Josephson junction, and the direction sign being a second direction sign represents a right-turning vertical direction of the corresponding Josephson junction relative to the previous Josephson junction.
21: The non-transitory computer-readable storage medium of any of clauses 16-20, wherein when the action parameter further comprises an adjustment parameter for adjusting the Josephson junction, performing the target script to obtain the layout of the Josephson junction array having a plurality of connected Josephson junctions comprises: after assigning the initial position value to the initial position parameter in the target script, assigning the first parameter value to the first structural parameter in the target script to obtain the Josephson junction; and after adjusting the obtained Josephson junction according to the adjustment parameter to obtain an adjusted Josephson junction, assigning the second parameter value to the second structural parameter in the target script, and assigning the connection parameter value to the connection parameter, so as to obtain the layout of the Josephson junction array having the plurality of connected Josephson junctions.
22: The non-transitory computer-readable storage medium of any of clauses 16-21, wherein the adjustment parameter comprises at least one of: a flipping parameter for a flipping operation of the Josephson junction, or a translation parameter for a translation operation of the Josephson junction.
23: The non-transitory computer-readable storage medium of any of clauses 16-22, wherein performing the target script to obtain the layout of the Josephson junction array having the plurality of connected Josephson junctions comprises: obtaining a value of a quantity parameter in the target script, wherein the quantity parameter is used for configuring the quantity of the plurality of Josephson junctions; and after assigning the value to the quantity parameter, performing the target script to obtain the layout of the Josephson junction array having connected Josephson junctions, wherein the quantity of the connected Josephson junctions is the assigned value.
24: The non-transitory computer-readable storage medium of any of clauses 16-23, wherein after performing the target script to obtain the layout of the Josephson junction array having the plurality of connected Josephson junctions, the operations further comprise: creating a target macro based on the target script, wherein the target macro is used for batch generation of reuse scripts of the Josephson junction array; and generating a replicated layout of the Josephson junction array based on the target macro.
25: The non-transitory computer-readable storage medium of any of clauses 16-24, wherein after performing the target script to obtain the layout of the Josephson junction array having the plurality of connected Josephson junctions, the operations further comprise: preparing a quantum device comprising the Josephson junction array based on the layout, wherein the quantum device comprises at least one of: a Fluxonium quantum bit, a quantum port, a ground plane, a coplanar waveguide, or a quantum component constructed based on the Fluxonium quantum bit.
26: The non-transitory computer-readable storage medium of any of clauses 16-25, further comprising: receiving a layout generation request of the Josephson junction array on a script interface; obtaining the original script in response to the generation request; receiving a layout generation instruction on the script interface; in response to the layout generation instruction, in the original script, assigning the first parameter value to the first structural parameter, assigning the second parameter value to the second structural parameter, assigning the initial position value to the initial position parameter, and assigning the connection parameter value to the connection parameter, so as to obtain the target script, and performing the target script to obtain the layout of the Josephson junction array having the plurality of connected Josephson junctions; and displaying the layout of the Josephson junction array on a preset display interface.
27: A computer device, comprising: a memory configured to store a computer program; and one or more processors configured to run the computer program stored in the memory, to cause the computer device to execute operations comprising: obtaining an original script that defines geometric parameters and action parameters, wherein the geometric parameters comprise a first structural parameter used for defining a geometric structure of a Josephson junction, and a second structural parameter used for defining a geometric structure of a metal wire configured to connect two adjacent Josephson junctions, wherein the action parameters comprise an initial position parameter used for defining an initial position of an initial Josephson junction, and a connection parameter used for defining a connection condition under which the metal wire connects two adjacent Josephson junctions; obtaining a first parameter value of the first structural parameter, a second parameter value of the second structural parameter, an initial position value of the initial position parameter, and a connection parameter value of the connection parameter; obtaining a target script by assigning from the original script: the first parameter value to the first structural parameter, the second parameter value to the second structural parameter, the initial position value to the initial position parameter, and the connection parameter value to the connection parameter; and performing the target script to obtain a layout of a Josephson junction array having a plurality of connected Josephson junctions.
28: The computer device of clause 27, wherein in the original script, the Josephson junction is represented by a vector point, the vector point comprises a coordinate parameter and a direction parameter, the coordinate parameter represents a central coordinate position of the represented Josephson junction, and the direction parameter represents a direction position of the next Josephson junction of the represented Josephson junction relative to the represented Josephson junction.
29: The computer device as either of clauses 27 or 28, wherein the connection condition is: one Josephson junction having no more than one adjacent Josephson junction in a horizontal direction and no more than one adjacent Josephson junction in a vertical direction.
30: The computer device of any of clauses 27-29, wherein the connection parameter is represented by a floating point number corresponding to the Josephson junction, the magnitude of the floating point number represents a distance between the corresponding Josephson junction and the previous Josephson junction, and a direction sign of the floating point number represents a direction of the corresponding Josephson junction relative to the previous Josephson junction.
31: The computer device of any of clauses 27-30, wherein the direction sign being a first direction sign represents a left-turning vertical direction of the corresponding Josephson junction relative to the previous Josephson junction, and the direction sign being a second direction sign represents a right-turning vertical direction of the corresponding Josephson junction relative to the previous Josephson junction.
32: The computer device of any of clauses 27-31, wherein when the action parameter further comprises an adjustment parameter for adjusting the Josephson junction, performing the target script to obtain the layout of the Josephson junction array having a plurality of connected Josephson junctions comprises: after assigning the initial position value to the initial position parameter in the target script, assigning the first parameter value to the first structural parameter in the target script to obtain the Josephson junction; and after adjusting the obtained Josephson junction according to the adjustment parameter to obtain an adjusted Josephson junction, assigning the second parameter value to the second structural parameter in the target script, and assigning the connection parameter value to the connection parameter, so as to obtain the layout of the Josephson junction array having the plurality of connected Josephson junctions.
33: The computer device of any of clauses 27-32, wherein the adjustment parameter comprises at least one of: a flipping parameter for a flipping operation of the Josephson junction, or a translation parameter for a translation operation of the Josephson junction.
34: The computer device of any of clauses 27-33, wherein performing the target script to obtain the layout of the Josephson junction array having the plurality of connected Josephson junctions comprises: obtaining a value of a quantity parameter in the target script, wherein the quantity parameter is used for configuring the quantity of the plurality of Josephson junctions; and after assigning the value to the quantity parameter, performing the target script to obtain the layout of the Josephson junction array having connected Josephson junctions, wherein the quantity of the connected Josephson junctions is the assigned value.
35: The computer device of any of clauses 27-34, wherein after performing the target script to obtain the layout of the Josephson junction array having the plurality of connected Josephson junctions, the operations further comprise: creating a target macro based on the target script, wherein the target macro is used for batch generation of reuse scripts of the Josephson junction array; and generating a replicated layout of the Josephson junction array based on the target macro.
36: The computer device of any of clauses 27-35, wherein after performing the target script to obtain the layout of the Josephson junction array having the plurality of connected Josephson junctions, the operations further comprise: preparing a quantum device comprising the Josephson junction array based on the layout, wherein the quantum device comprises at least one of: a Fluxonium quantum bit, a quantum port, a ground plane, a coplanar waveguide, or a quantum component constructed based on the Fluxonium quantum bit.
37: The computer device of any of clauses 27-36, further comprising: receiving a layout generation request of the Josephson junction array on a script interface; obtaining the original script in response to the generation request; receiving a layout generation instruction on the script interface; in response to the layout generation instruction, in the original script, assigning the first parameter value to the first structural parameter, assigning the second parameter value to the second structural parameter, assigning the initial position value to the initial position parameter, and assigning the connection parameter value to the connection parameter, so as to obtain the target script, and performing the target script to obtain the layout of the Josephson junction array having the plurality of connected Josephson junctions; and displaying the layout of the Josephson junction array on a preset display interface.

The foregoing descriptions are exemplary implementations of the present disclosure. It is noted that a person of ordinary skill in the art may make some improvements and modifications without departing from the principle of the present disclosure, and the improvements and modifications shall fall within the protection scope of the present disclosure.

What is claimed is:

1. A method for generating a layout of a Josephson junction array, comprising:
obtaining an original script that defines geometric parameters and action parameters,
wherein the geometric parameters comprise a first structural parameter used for defining a geometric structure of a Josephson junction and a second structural parameter used for defining a geometric structure of a metal wire configured to connect two adjacent Josephson junctions,
wherein the action parameters comprise an initial position parameter used for defining an initial position of an initial Josephson junction and a connection parameter used for defining a connection condition under which the metal wire connects two adjacent Josephson junctions;
obtaining a first parameter value of the first structural parameter, a second parameter value of the second structural parameter, an initial position value of the initial position parameter, and a connection parameter value of the connection parameter;
obtaining a target script by assigning from the original script:
the first parameter value to the first structural parameter,
the second parameter value to the second structural parameter,
the initial position value to the initial position parameter, and
the connection parameter value to the connection parameter; and
performing the target script to obtain a layout of a Josephson junction array having a plurality of connected Josephson junctions.

2. The method of claim 1, wherein in the original script, the Josephson junction is represented by a vector point, the vector point comprises a coordinate parameter and a direction parameter, the coordinate parameter represents a central coordinate position of the represented Josephson junction, and the direction parameter represents a direction position of the next Josephson junction of the represented Josephson junction relative to the represented Josephson junction.

3. The method of claim 1, wherein the connection condition is: one Josephson junction having no more than one adjacent Josephson junction in a horizontal direction and no more than one adjacent Josephson junction in a vertical direction.

4. The method of claim 3, wherein the connection parameter is represented by a floating point number corresponding to the Josephson junction, the magnitude of the floating point number represents a distance between the corresponding Josephson junction and the previous Josephson junction, and a direction sign of the floating point number represents a direction of the corresponding Josephson junction relative to the previous Josephson junction.

5. The method of claim 4, wherein the direction sign being a first direction sign represents a left-turning vertical direction of the corresponding Josephson junction relative to the previous Josephson junction, and the direction sign being a second direction sign represents a right-turning vertical direction of the corresponding Josephson junction relative to the previous Josephson junction.

6. The method of claim 1, wherein when the action parameter further comprises an adjustment parameter for adjusting the Josephson junction, performing the target script to obtain the layout of the Josephson junction array having a plurality of connected Josephson junctions comprises:
after assigning the initial position value to the initial position parameter in the target script, assigning the first parameter value to the first structural parameter in the target script to obtain the Josephson junction; and
after adjusting the obtained Josephson junction according to the adjustment parameter to obtain an adjusted Josephson junction, assigning the second parameter value to the second structural parameter in the target script, and assigning the connection parameter value to the connection parameter, so as to obtain the layout of the Josephson junction array having the plurality of connected Josephson junctions.

7. The method of claim 6, wherein the adjustment parameter comprises at least one of: a flipping parameter for a flipping operation of the Josephson junction, or a translation parameter for a translation operation of the Josephson junction.

8. The method of claim 1, wherein performing the target script to obtain the layout of the Josephson junction array having the plurality of connected Josephson junctions comprises:
obtaining a value of a quantity parameter in the target script, wherein the quantity parameter is used for configuring the quantity of the plurality of Josephson junctions; and
after assigning the value to the quantity parameter, performing the target script to obtain the layout of the Josephson junction array having connected Josephson junctions, wherein the quantity of the connected Josephson junctions is the assigned value.

9. The method of claim 8, wherein after performing the target script to obtain the layout of the Josephson junction array having the plurality of connected Josephson junctions, the method further comprises:
creating a target macro based on the target script, wherein the target macro is used for batch generation of reuse scripts of the Josephson junction array; and
generating a replicated layout of the Josephson junction array based on the target macro.

10. The method of claim 1, wherein after performing the target script to obtain the layout of the Josephson junction array having the plurality of connected Josephson junctions, the method further comprises:
preparing a quantum device comprising the Josephson junction array based on the layout, wherein the quantum device comprises at least one of: a Fluxonium quantum bit, a quantum port, a ground plane, a coplanar waveguide, or a quantum component constructed based on the Fluxonium quantum bit.

11. The method of claim 1, further comprising:
receiving a layout generation request of the Josephson junction array on a script interface;
obtaining the original script in response to the generation request;
receiving a layout generation instruction on the script interface;
in response to the layout generation instruction, obtaining the target script and performing the target script; and
displaying the layout of the Josephson junction array on a preset display interface.

12. A non-transitory computer-readable storage medium storing a program that is executable by a device to cause the device to perform operations comprising:
obtaining an original script that defines geometric parameters and action parameters,
wherein the geometric parameters comprise a first structural parameter used for defining a geometric structure of a Josephson junction, and a second structural parameter used for defining a geometric structure of a metal wire configured to connect two adjacent Josephson junctions,
wherein the action parameters comprise an initial position parameter used for defining an initial position of an initial Josephson junction, and a connection parameter used for defining a connection condition under which the metal wire connects two adjacent Josephson junctions;
obtaining a first parameter value of the first structural parameter, a second parameter value of the second structural parameter, an initial position value of the initial position parameter, and a connection parameter value of the connection parameter;
obtaining a target script by assigning from the original script:
the first parameter value to the first structural parameter,
the second parameter value to the second structural parameter,
the initial position value to the initial position parameter, and
the connection parameter value to the connection parameter; and
performing the target script to obtain a layout of a Josephson junction array having a plurality of connected Josephson junctions.

13. The non-transitory computer-readable storage medium of claim 12, wherein in the original script, the Josephson junction is represented by a vector point, the vector point comprises a coordinate parameter and a direction parameter, the coordinate parameter represents a central coordinate position of the represented Josephson junction, and the direction parameter represents a direction position of the next Josephson junction of the represented Josephson junction relative to the represented Josephson junction.

14. The non-transitory computer-readable storage medium of claim 12, wherein the connection condition is: one Josephson junction having no more than one adjacent Josephson junction in a horizontal direction and no more than one adjacent Josephson junction in a vertical direction.

15. The non-transitory computer-readable storage medium of claim 14, wherein the connection parameter is represented by a floating point number corresponding to the Josephson junction, the magnitude of the floating point number represents a distance between the corresponding Josephson junction and the previous Josephson junction, and a direction sign of the floating point number represents a direction of the corresponding Josephson junction relative to the previous Josephson junction.

16. The non-transitory computer-readable storage medium of claim 15, wherein the direction sign being a first direction sign represents a left-turning vertical direction of the corresponding Josephson junction relative to the previous Josephson junction, and the direction sign being a second direction sign represents a right-turning vertical direction of the corresponding Josephson junction relative to the previous Josephson junction.

17. The non-transitory computer-readable storage medium of claim 12, wherein when the action parameter further comprises an adjustment parameter for adjusting the Josephson junction, performing the target script to obtain the layout of the Josephson junction array having a plurality of connected Josephson junctions comprises:
after assigning the initial position value to the initial position parameter in the target script, assigning the first parameter value to the first structural parameter in the target script to obtain the Josephson junction; and
after adjusting the obtained Josephson junction according to the adjustment parameter to obtain an adjusted Josephson junction, assigning the second parameter value to the second structural parameter in the target script, and assigning the connection parameter value to the connection parameter, so as to obtain the layout of the Josephson junction array having the plurality of connected Josephson junctions.

18. The non-transitory computer-readable storage medium of claim 17, wherein the adjustment parameter comprises at least one of: a flipping parameter for a flipping operation of the Josephson junction, or a translation parameter for a translation operation of the Josephson junction.

19. The non-transitory computer-readable storage medium of claim 12, wherein performing the target script to obtain the layout of the Josephson junction array having the plurality of connected Josephson junctions comprises:
obtaining a value of a quantity parameter in the target script, wherein the quantity parameter is used for configuring the quantity of the plurality of Josephson junctions; and
after assigning the value to the quantity parameter, performing the target script to obtain the layout of the Josephson junction array having connected Josephson junctions, wherein the quantity of the connected Josephson junctions is the assigned value.

20. A computer device, comprising:
a memory configured to store a computer program; and
one or more processors configured to run the computer program stored in the memory, to cause the computer device to execute operations comprising:
obtaining an original script that defines geometric parameters and action parameters,
wherein the geometric parameters comprise a first structural parameter used for defining a geometric structure of a Josephson junction, and a second structural parameter used for defining a geometric structure of a metal wire configured to connect two adjacent Josephson junctions,
wherein the action parameters comprise an initial position parameter used for defining an initial position of an initial Josephson junction, and a connection parameter used for defining a connection condition under which the metal wire connects two adjacent Josephson junctions;
obtaining a first parameter value of the first structural parameter, a second parameter value of the second structural parameter, an initial position value of the initial position parameter, and a connection parameter value of the connection parameter;
obtaining a target script by assigning from the original script:
the first parameter value to the first structural parameter,
the second parameter value to the second structural parameter,
the initial position value to the initial position parameter, and
the connection parameter value to the connection parameter; and
performing the target script to obtain a layout of a Josephson junction array having a plurality of connected Josephson junctions.
